(19) United States
(12) Patent Application Publication
(10) Pub. No.: US 2025/0308832 A1
(43) Pub. Date: Oct. 2, 2025

(54) STABILIZING A TIP WIRE OF AN ELECTRON SOURCE

(71) Applicant: Applied Materials Israel Ltd., Rehovot (IL)

(72) Inventor: Asaf GUTMAN, Gan Hashomron (IL)

(21) Appl. No.: 19/091,747

(22) Filed: Mar. 26, 2025

(30) Foreign Application Priority Data
Mar. 31, 2024 (IL) 311890

(51) Int. Cl. H01J 37/065; H01J 37/26

(52) U.S. Cl. CPC H01J 37/065; H01J 37/261; H01J 2237/032; H01J 2237/06375; H01J 2237/2602

(57) ABSTRACT

An electron source that includes (a) an electron emitter that has an emitter tip; (b) a support element that is connected to the emitter tip; and (c) a vibration suppressor that (i) comprises an coupling portion, and (ii) is in mechanical communication with the electron emitter, wherein the vibration suppressor is configured to stabilize the emitter tip by absorbing vibrational energy of the emitter tip.

### RELATED APPLICATIONS

This application claims the benefit of priority from Israel Patent Application No. 311890, filed on Mar. 31, 2024, which is incorporated herein by reference.

### BACKGROUND

Charged particle systems such as electron beam evaluation systems are configured to illuminate a sample with a focused electron beam. Examples of electron beam evaluation systems include a scanning electron microscope (SEM), a transmission electron microscope (TEM), a scanning transmission electron microscope (STEM), a focused ion beam imager, and the like. There are various types of scanning electron microscopes—including a review scanning electron microscope and a critical dimension scanning electron microscope. Examples of scanning electron microscopes include the SEMVISION™ system and the VERISEM™ system of Applied materials Inc. of Santa Clara, California.

The focused electron beam is generated using an electron source that includes a tip wire that ends with a sharp tip from which electrons are extracted. There are different types of tips such as a thermos-ionic emitter and a cold field emitter. The emission of an electron from a thermos-ionic emitter requires to provide to the tip both an electrical energy and thermal energy. The emission of an electron from a cold field emitter requires electrical energy.

In a cold field emitter, the tip wire is welded to a support element that is also used to provide the electrical energy to the wire.

The electron beam evaluation system is usually installed within a noisy environment and includes multiple moving elements (such as a mechanical stage, one or more motors, and the like) that move during the evaluation process. The wire tip is very light and tends to mechanically oscillate due to the noisy environment and due to the movement of the moving elements.

The oscillation of the tip wire distorts the path of the extracted electrons—which in turn reduces the quality of any evaluation executed by the electron beam evaluation system.

To reduce the impact of the noisy environment, the entire electron beam evaluation system is being shielded using an acoustic shield that is costly, large, and heavy.

There is a growing need to reduce the vibrations of the tip wire.

### SUMMARY

According to an embodiment, there is provided an electron source that includes an electron emitter that has an emitter tip, a support element that is connected to the emitter tip, and a vibration suppressor that includes an coupling portion, and is in mechanical communication with the electron emitter, wherein the vibration suppressor is configured to stabilize the emitter tip by absorbing vibrational energy of the emitter tip.

According to an embodiment, there is provided a method for stabilizing an electron emitter, the method includes (a) emitting electrons by an electron source, the electron source includes an electron emitter, a support element and a vibration suppressor, the electron emitter that has an emitter tip, the support element that is connected to the electron emitter, the vibration suppressor includes a coupling portion, and (ii) is in mechanical communication with the electron emitter; and (b) stabilizing, by the vibration suppressor, the emitter tip by absorbing vibrational energy of the emitter tip.

According to an embodiment, there is provided a charged particle system that includes (a) an electron source that includes an electron emitter that has an emitter tip, a support element that is connected to the emitter tip, and a vibration suppressor that (i) includes an intermediate portion, and (ii) is in mechanical communication with the electron emitter, wherein the vibration suppressor is configured to stabilize the emitter tip by absorbing vibrational energy of the emitter tip; (b) a sensing unit; and (c) optics configured to illuminate a sample with an electron beam that includes electrons emitted from the electron tip, and (ii) direct to the sensing unit charged particles emitted from the sample due to the illumination of the sample with the electron beam.

### BRIEF DESCRIPTION OF THE DRAWINGS

The subject matter regarded as the embodiment is particularly pointed out and distinctly claimed in the concluding coupling portion of the specification. The embodiment, however, both as to organization and method of operation, together with specimen s, features, and advantages thereof, may best be understood by reference to the following detailed description when read with the accompanying drawings in which:

FIG. 1 illustrates an example of an electron source;

FIG. 2 illustrates an example of an electron source and additional components of a charged particle system;

FIG. 3 illustrates an example of an electron source and additional components of a charged particle system;

FIG. 4 illustrates an example of an electron source;

FIG. 5 illustrates an example of a charged particle system; and

FIG. 6 illustrates an example of a method.

### DETAILED DESCRIPTION OF THE DRAWINGS

A stress-strain curve is a graphical depiction of a material's behavior when subjected to increasing loads. Stress is defined as the ratio of force to cross-sectional area, while strain is defined as the ratio of the change in length of a dimension to the dimension's original length.

A stress-strain curve of a material defines when the material is elastic (can be regarded as an elastic material) and when the material is plastic (can be regarded as a plastic material).

An element made of a material that is within a linear part of the stress-strain curve is regarded as an elastic element. It should be noted that the stress-strain curve of the material may also include a non-linear part that includes a first sub-part that is regarded as elastic and a second sub-part that is regarded as plastic (inelastic).

An element that undergoes a certain deformation once loaded, and then fully recovers to its state before the loading—once the load in been removed—is an elastic element.

An element that undergoes a certain deformation once loaded, and then fails to fully recover to its state before the loading—once the load in been removed—is regarded as a plastic element.

Examples of the Young Modulus (slope of linear regions of stress-strain curves) of various materials include:
a. Stainless steel, American Iron and Steel Institute (AISI) 302-180.
b. Aluminum alloys —70.
c. Brass —102-125.
d. Copper 117.
e. Titanium alloy —105-120.
f. Tungsten 400-410.

Any reference to a tuned mass damper should be applied mutatis mutandis to a dynamic vibration absorber.

There is provided an electron source, the electron source includes (a) an electron emitter that has an emitter tip, (b) a support element that is connected to the emitter tip, and (c) a vibration suppressor that includes a coupling portion and is in mechanical communication with the electron emitter. The vibration suppressor is configured to stabilize the emitter tip by absorbing vibrational energy of the emitter tip.

According to an embodiment, the vibration suppressor is directly connected to the emitter tip.

According to an embodiment, the vibration suppressor is welded to the emitter tip.

According to an embodiment, the vibration suppressor and the emitter tip belong to the same mechanical element.

According to an embodiment, the vibration suppressor is indirectly connected to the emitter tip—and there is at least one mechanical element connected between the vibration suppressor and the emitter tip.

According to an embodiment, any direct or indirect connection is configured to facilitate an absorbance (partial of full) of the vibrational energy of the emitter tip.

According to an embodiment the support element is electrically conductive and is configured to convey current to the electron emitter. Additionally or alternatively, the support element is configured to electrically bias the electron emitter.

According to an embodiment, the support element is a wire or a filament, and the like.

According to an embodiment, the vibrational energy is consumed by the vibration suppressor thereby reducing and even eliminating the vibrations of the electron emitter.

According to an embodiment the entire vibration suppressor is elastic—not just the coupling portion—and does not include a separate mass element. The vibration suppressor is in mechanical communication with the electron emitter. For example—the coupling portion own mass acts as the mass element.

According to an embodiment, the vibration suppressor includes a mass and the coupling portion. The coupling portion is in mechanical communication with the electron emitter and the mass element.

According to an embodiment, the electron emitter has an electron emitter longitudinal axis, the coupling portion has a coupling portion longitudinal axis, and the electron emitter longitudinal axis is aligned with the coupling portion longitudinal axis.

According to an embodiment, the mass is radially symmetrical, and the coupling portion is radially symmetrical.

According to an embodiment, the mass is wider than the coupling portion.

According to an embodiment, the mass and the coupling portion form a dynamic vibration absorber.

According to an embodiment, the electron emitter is downstream to the mass element.

According to an embodiment, the support element is electrically coupled to a pair of conductors that extend from an insulating unit.

According to an embodiment, the distal ends of the pair of conductors are closer to the insulating unit than the mass element.

According to an embodiment, the electron emitter is a wire that ends with the emitter tip. A distance between the mass and a contact point between the wire and the support element (for example a support filament) exceeds a distance between the emitter tip and the contact point.

According to an embodiment, the distance between the mass and the contact point exceeds by a factor of at least three, the distance between the emitter tip and the contact point.

According to an embodiment, the mass may be made from different material than the coupling portion and/or the emitter tip.

According to an embodiment the mass element is denser than the coupling portion. In this case the mass element and the coupling portion may be of the same width.

According to an embodiment, the mass element has a mass that differs from a mass of the coupling portion.

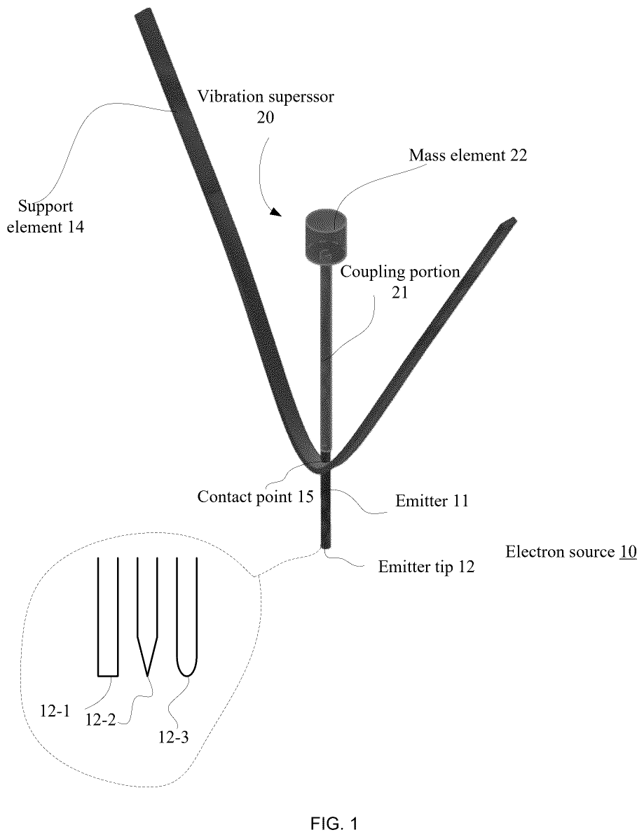

FIG. 1 illustrates an example of an electron source 10 that includes electron emitter 11 that has an emitter tip 12, support element 14 that is connected to the emitter tip, and vibration suppressor 20 that includes a coupling portion 21 and is in mechanical communication with the electron emitter.

In FIG. 1 the vibration suppressor 20 is illustrated as including, in addition to the coupling portion 21, a mass element 22.

In FIG. 1 the mass element 22 is wider than the coupling portion 21, the mass element 22 and the coupling portion 21 exhibit a radially symmetry, the mass element 22 is located upstream to the contact point 15 between the support element 14 and the emitter 11, the distance between the mass element and contact point 15 exceeds the distance between the contact point and the emitter tip 12.

The emitter tip 12 may be of any shape—for example have a triangle shape cross section (see 12-2), have a rectangular shape cross section (see 12-1), have a rounded shape cross section (see 12-3)—or any other shape.

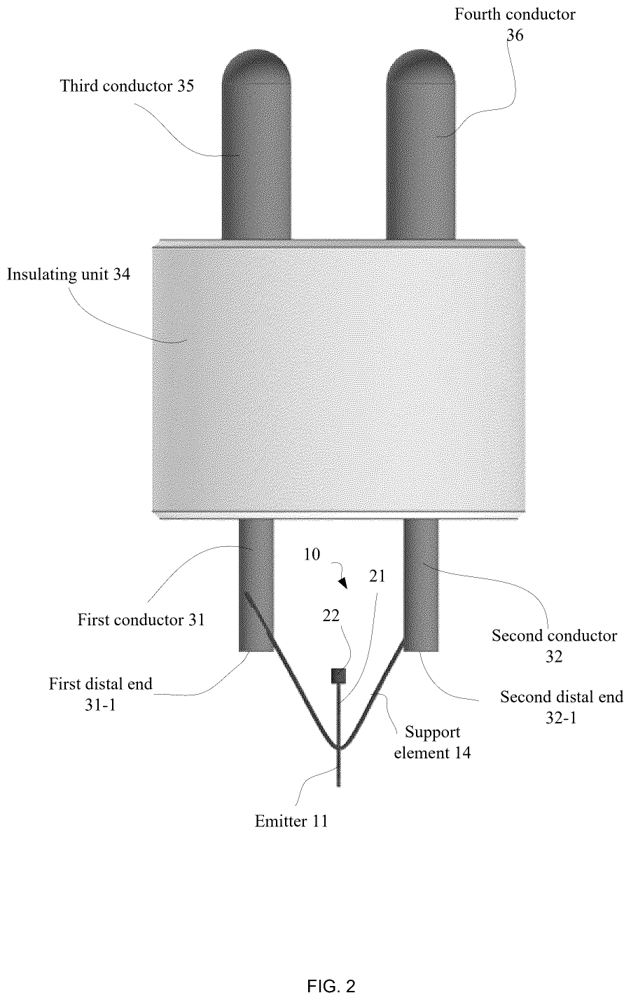

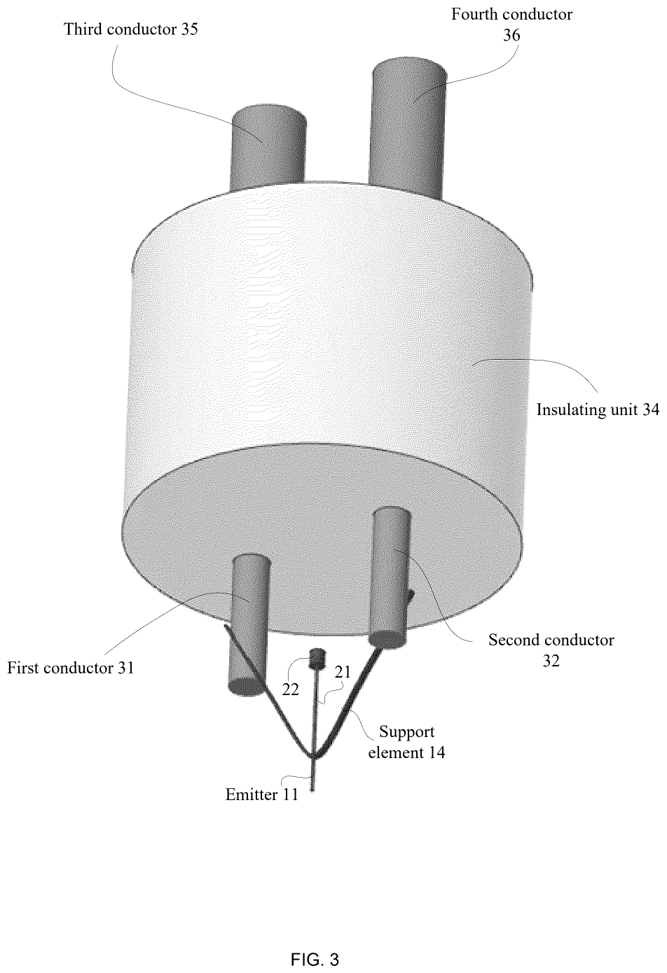

FIGS. 2 and 3 illustrate an example of electron source 10 and additional components of a charged particle system.

Electron source 10 includes electron emitter 11 that has an emitter tip 12, support element 14 that is connected to the emitter tip, and a vibration suppressor that includes mass element 22 and coupling portion 21.

In FIGS. 2 and 3 the support element 14 is electrically coupled to a pair of conductors (including first conductor 31 having first distal end 31-1, and second conductor 32 having second distal end 32-1) that extend from an insulating unit 34. The distal ends of the pair of conductors are closer to the insulating unit 34 than the mass element 22.

FIGS. 2 and 3 also illustrates another pair of conductors (including third conductor 35 and fourth conductor 36) that extend from another side of the insulating unit 32.

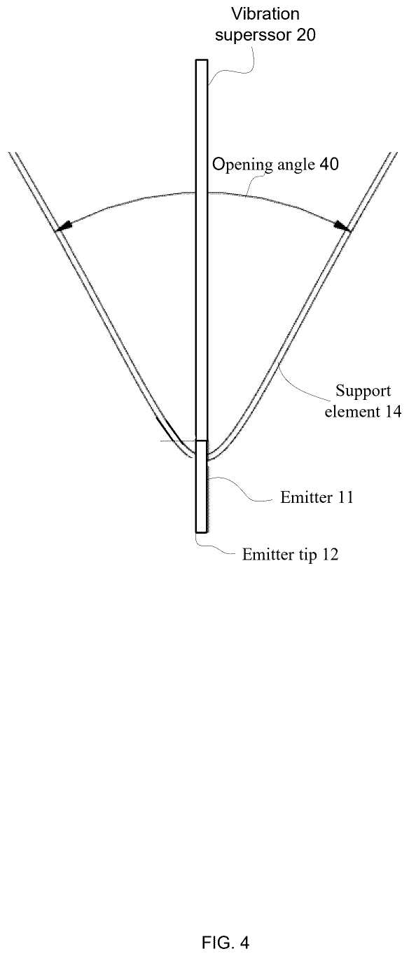

FIG. 4 illustrates support element 14, electron emitter 11 having an emitter tip 11 and a vibration suppressor 20. The vibration suppressor may be elastic or plastic. In contrary to the vibration suppressor of FIGS. 1-3—that includes a mass element in addition to the coupling portion.

FIG. 4 illustrates an example of the opening angle (denoted 40) of the support element 14.

According to an embodiment the support element is made of Tungsten, although other materials may be used.

According to an embodiment the weight of the coupling portion ranges between 0.0001 and 0.008 gram, or ranges between 0.00001 and 0.0008 grams, or is below one milligrams, or exceeds one milligrams.

According to an embodiment the weight of the mass element ranges between 0.001 and 0.008 gram, or ranges between 0.0001 and 0.008 grams, or is below ten milligrams, or exceeds ten milligrams.

According to an embodiment, the mass is heavier than the coupling portion by a factor that ranges between 2 to 20, between 6 to 10, above 10 or below 2.

According to an embodiment, the width of the mass is less than one millimeter or above one millimeter.

According to an embodiment, the width of the elastic element is less than one tenth of millimeter or above one tenth of millimeter.

According to an embodiment, the length of the elastic element ranges between 1.5 and 3 millimeters, or above three millimeters, or below 1.5 millimeters.

According to an embodiment, the coupling portion is longer than the mass by a factor that ranges between 2 to 10, between 4 to 5, above 10 or below 2.

According to an embodiment, the vibration suppressor is designed using a dynamic vibration absorber/tuned mass damper calculations.

It has been shown that the vibration suppressor reduces vibrations of the emitter tip, at 6 Khz from having an amplitude that exceeded one hundred and fifty millimeter to less than 1 micron.

According to an embodiment the vibration suppressor is configured to reduce vibration in any other frequency—for example any vibration frequency within a range of 2 KHz to 10 KHz.

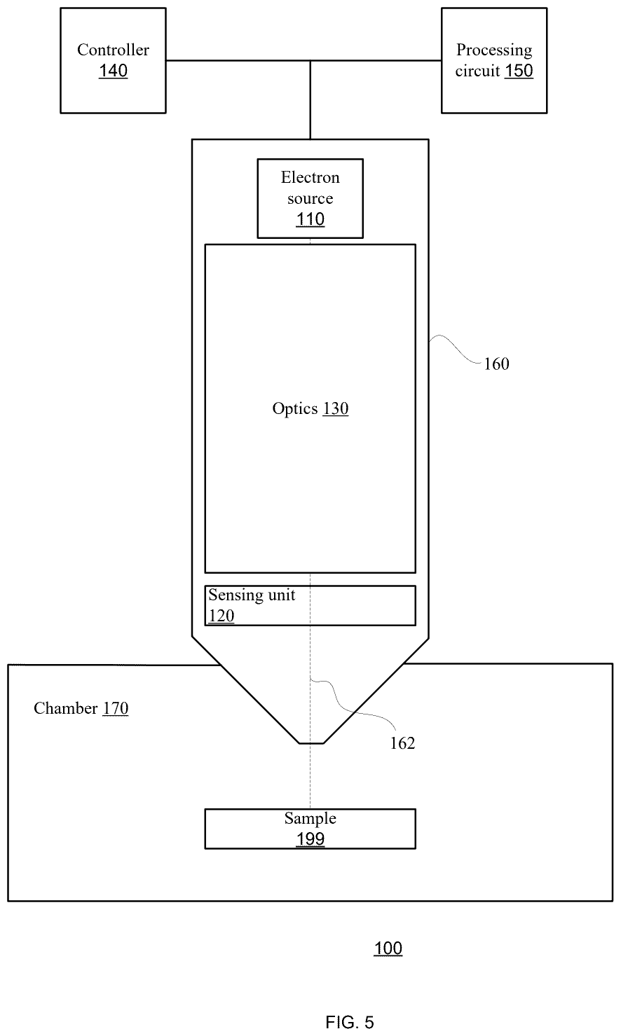

FIG. 5 illustrates an example of a charged particle system 100.

According to an embodiment, charged particle system 100 includes:
a. An electron source 110 that includes an electron emitter that has an emitter tip, a support element that is connected to the emitter tip, and a vibration suppressor that includes an coupling portion, and is in mechanical communication with the electron emitter, wherein the vibration suppressor is configured to stabilize the emitter tip by absorbing vibrational energy of the emitter tip. FIG. 5 illustrates electron beam 162 formed from electrons emitted from the emitter tip.
b. Sensing unit 120. According to an embodiment the sensing unit includes one or more sensors that are selected out of secondary electron sensors, backscattered electron sensors, x-ray sensors, photon sensors, and the like. In FIG. 5 the sensing optics is included within column 160—but at least one sensor may be located outside of column 160.
c. Optics 130 configured to illuminate a sample with an electron beam that comprises electrons emitted from the electron tip, and (ii) direct to the sensing unit charged particles emitted from the sample due to the illumination of the sample with the electron beam. According to an embodiment, the optics 130 include one or more objective lenses, one or more beam splitters, one or more polarizers, one or more scanning elements, and the like. In FIG. 5 optics 130 is illustrates as being located between the electron optics and the sensing unit 120—but at least one component of optics may be located between sensing unit and the sample 199.
d. Controller 140 configured to control the charged particle system 100.
e. Processing circuit 150 configured to process detection signals generated by the sensing unit 120.
f. Column 160.
g. Vacuum chamber 170.

According to an embodiment a stiffness of the vibration suppressor and the mass of the vibration suppressor are optimized or at least designed to obtain a predefined tradeoff.

According to an embodiment the vibration suppressor is designed by using tuned mass damper calculations aimed to define the tuned mass damper frequency to effectively reduce the tip vibration at a desired frequency.

According to an embodiment the vibration suppressor is designed by using dynamic vibration absorbers calculations.

According to an embodiment the vibration suppressor is designed based on at least one of the following:
a. Given to a required stiffness, a material of the vibration suppressor is selected to have a Young Modulus to achieve the required stiffness.
b. When the vibration suppressor does not have a dedicated mass element—a material density of the vibration suppressor is selected to meet other design requirements.
c. The ability to connect (by welding or other methods) the mass element to the coupling portion.
d. Electrical and thermal properties of the vibration suppressor should be defined so that the vibration suppressor will not negatively impact the operation of the emitter.
e. Vacuum and/or outgassing considerations—the vibration suppressor should be made of materials that do not degas above a defined value.

According to an embodiment, the vibration suppression is very small—which may complicate the tuning of the vibration suppressor. According to an embodiment, the vibration suppressor is tuned to different frequencies by one or more of the following: (i) changing the mass element (by using different material, two or more materials combinations, different geometry etc.), (ii) changing the stiffness of the coupling element (either by changing the material properties and/or the geometry), (iii) making the coupling portion of different materials with different properties, (iv) making the coupling portion from shape-memory and/or super elasticity alloys (such as “Nitinol”—Nickel Titanium), (v) utilizing other phase-transition material properties, such as “Reversible solid-state phase transformation” (“Martensitic Transformation”), at which the material shifts from the Austenite cubic structure at one temperature and/or electrical condition, to a Martensite, mono-crystal structure at 2^{nd} temperature and/or electrical condition. This way, the stiffness of the elastic element can be tuned, (vi) utilizing thermoelectric effect such as the “Seebeck” effect, Peltier effect and Thomson effect) as “stand-alone” or with combination with the above method. For example: electric current can change the temperature of a memory-shape alloy and change its behavior. Using these effects can also “close the loop” and make the vibration suppressor a “self-tuning” device, which tunes itself to the emitter new conditions based on its change in electrical/temperature conditions, or (vii) applying magnetic fields and/or electrical fields and/or electro-magnetic fields and/or forces on the vibration suppressor.

According to an embodiment, the vibration suppressor is a dynamic vibration absorber and consists essentially of a coupling element and a mass element.

According to an embodiment the vibration suppressor includes a coupling portion, a mass element, and an additional damping element (a tuned mass damper).

According to an embodiment, the additional damping element is configured to reduce two side-peaks the dynamic vibration absorber produces.

According to an embodiment, the coupling element is designed apply one of Rayleigh damping, or hysteresis damping), in which the response legs the applied force, and is based on complex molecular interaction within the material.

According to an embodiment, the electron source is a part of at least one of a charged particle system such as a scanning electron microscope, a transmissive electron microscope, an electron imager and the like.

Non-limiting examples of scanning electron microscopes include the VERITYSEM™ Critical Dimension microscope and the SEMVISION™ Review microscope of APPLIED MATERIALS™ of Santa Clara, California, US.

A non-limiting example of an electron imager is the PRIMEVISION™ of APPLIED MATERIALS™ of Santa Clara, California, US.

Non limiting examples of vibration suppressors are illustrated in FIGS. 1-4.

According to an embodiment, the vibration suppressor is elastic, and in mechanical communication with the electron emitter, wherein the vibration suppressor is configured to stabilize the emitter tip by absorbing vibrational energy of the emitter tip.

According to an embodiment, the vibration suppressor includes a mass element and the coupling portion, the coupling portion is in mechanical communication with the electron emitter and the mass element, wherein the vibration suppressor is configured to stabilize the emitter tip by absorbing vibrational energy of the emitter tip.

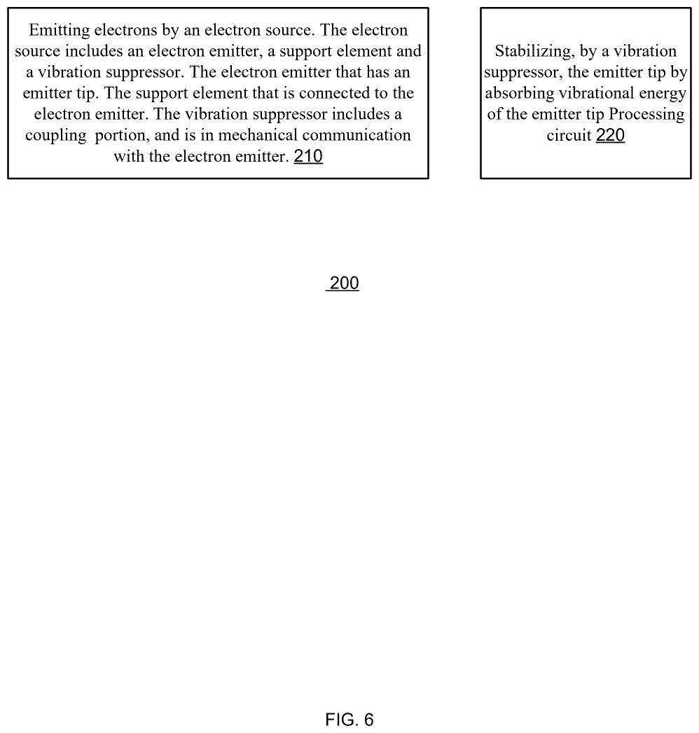

FIG. 6 illustrates an example of method 200 for stabilizing an electron emitter.

According to an embodiment, method 200 includes step 210 of emitting electrons by an electron source. The electron source includes an electron emitter, a support element, and a vibration suppressor. The electron emitter that has an emitter tip. The support element that is connected to the electron emitter. The vibration suppressor includes a coupling portion and is in mechanical communication with the electron emitter.

According to an embodiment, method 200 also includes step 220 of stabilizing, by a vibration suppressor, the emitter tip by absorbing vibrational energy of the emitter tip.

Non limiting examples of vibration suppressors are illustrated in FIGS. 1-4.

According to an embodiment, the vibration suppressor is elastic, and in mechanical communication with the electron emitter, wherein the vibration suppressor is configured to stabilize the emitter tip by absorbing vibrational energy of the emitter tip.

According to an embodiment, the vibration suppressor includes a mass element and the coupling portion, the coupling portion is in mechanical communication with the electron emitter and the mass element, wherein the vibration suppressor is configured to stabilize the emitter tip by absorbing vibrational energy of the emitter tip.

It will be appreciated that for simplicity and clarity of illustration, elements shown in the figures may be either of scale or may have been drawn out of scale. For example, the dimensions of some of the elements may be exaggerated relative to other elements for clarity. Yet for another example—the dimensions of elements are of scale. Further, where considered appropriate, reference numerals may be repeated among the figures to indicate corresponding or analogous elements.

In the foregoing detailed description, numerous specific details are set forth to provide a thorough understanding of the embodiments of the disclosure.

However, it will be understood by those skilled in the art that the present embodiments of the disclosure may be practiced without these specific details. In other instances, well-known methods, procedures, and components have not been described in detail so as not to obscure the present embodiments of the disclosure.

The subject matter regarded as the embodiments of the disclosure is particularly pointed out and distinctly claimed in the concluding coupling portion of the specification. The embodiments of the disclosure, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the disclosure may for the most part, be implemented using mechanical components and circuits known to those skilled in the art, details will not be explained in any greater extent than that considered necessary as illustrated above, for the understanding and appreciation of the underlying concepts of the present embodiments of the disclosure and in order not to obfuscate or distract from the teachings of the present embodiments of the disclosure.

Any reference in the specification to a method should be applied mutatis mutandis to a manipulator capable of executing the method.

Any reference in the specification to a manipulator should be applied mutatis mutandis to a method that may be executed by the manipulator.

The term “and/or” means additionally or alternatively. For example, A and/or B means only A, or only B or A and B.

In the foregoing description, numerous specific details are set forth to provide a thorough understanding of the embodiments of the disclosure.

However, it will be understood by those skilled in the art that the present embodiments of the disclosure may be practiced without these specific details. In other instances, well-known methods, procedures, and components have not been described in detail so as not to obscure the present embodiments of the disclosure.

The subject matter regarded as the embodiments of the disclosure is particularly pointed out and distinctly claimed in the concluding coupling portion of the specification. The embodiments of the disclosure, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Any reference in the specification to a support unit should be applied mutatis mutandis to a method that may be executed by the support unit.

The term “and/or” means additionally or alternatively. For example, A and/or B means only A, or only B or A and B.

In the foregoing specification, the embodiments of the disclosure have been described with reference to specific examples of embodiments. It will, however, be evident that various modifications and changes may be made therein without departing from the broader spirit and scope of the appended claims.

Moreover, the terms “front,” “back,” “top,”, “bottom,” “over,” “under” and the like in the description and in the claims, if any, are used for descriptive purposes and not necessarily for describing permanent relative positions. It is understood that the terms so used are interchangeable under appropriate circumstances such that the embodiments of the disclosure described herein are, for example, capable of operation in other orientations than those illustrated or otherwise described herein.

Any reference to the term “comprising” or “having” or “including” should be applied mutatis mutandis to “consisting of” and/or should be applied mutatis mutandis to “consisting essentially of”.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps than those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any claim containing such introduced claim element to embodiments containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the embodiments have been illustrated and described herein, many modifications, substitutions, changes, and equivalents will now occur to those of ordinary skill in the art. It is, therefore, to be understood that the appended claims are intended to cover all such modifications and changes as fall within the true spirit of the embodiment.

We claim:

1. An electron source, comprising:
an electron emitter that has an emitter tip;
a support element that is connected to the emitter tip; and
a vibration suppressor that (i) comprises a coupling portion, and (ii) is in mechanical communication with the electron emitter, wherein the vibration suppressor is configured to stabilize the emitter tip by absorbing vibrational energy of the emitter tip.

2. The electron source according to claim 1, wherein the coupling portion is plastic.

3. The electron source according to claim 1, wherein the coupling portion is elastic.

4. The electron source according to claim 1, wherein the vibration suppressor is, and in mechanical communication with the electron emitter, wherein the vibration suppressor is configured to stabilize the emitter tip by absorbing vibrational energy of the emitter tip.

5. The electron source according to claim 1, wherein the vibration suppressor that comprises a mass element and the coupling portion, the coupling portion is in mechanical communication with the electron emitter and the mass element, wherein the vibration suppressor is configured to stabilize the emitter tip by absorbing vibrational energy of the emitter tip.

6. The electron source according to claim 5, wherein the electron emitter has an electron emitter longitudinal axis, the coupling portion has a coupling portion longitudinal axis, and wherein the electron emitter longitudinal axis is aligned with the coupling portion longitudinal axis.

7. The electron source according to claim 5, wherein the wherein the mass element is radially symmetrical, the coupling portion is radially symmetrical.

8. The electron source according to claim 5, wherein the mass element is wider than the coupling portion.

9. The electron source according to claim 5, wherein the mass element and the coupling portion form a dynamic vibration absorber.

10. The electron source according to claim 5, wherein the electron emitter is downstream to the mass element.

11. The electron source according to claim 10, wherein the support element is electrically coupled to a pair of conductors that extend from an insulating unit, wherein distal ends of the pair of conductors are closer to the insulating unit than the mass element.

12. The electron source according to claim 5, wherein the electron emitter is a wire that ends with the emitter tip, wherein a distance between the mass element and a contact point between the wire and the support element exceeds a distance between the emitter tip and the contact point.

13. The electron source according to claim 12, wherein the distance between the mass element and the contact point exceeds by a factor of at least three, the distance between the emitter tip and the contact point.

14. The electron source according to claim 12, wherein the mass element is denser than the coupling portion.

15. The electron source according to claim 12, wherein the mass element has a mass that differs from a mass of the coupling portion.

16. A method for stabilizing an electron emitter, the method comprises:
emitting electrons by an electron source, the electron source includes an electron emitter, a support element and a vibration suppressor, the electron emitter that has an emitter tip, the support element that is connected to the electron emitter, the vibration suppressor comprises a coupling portion, and (ii) is in mechanical communication with the electron emitter; and
stabilizing, by the vibration suppressor, the emitter tip by absorbing vibrational energy of the emitter tip.

17. The method according to claim 16, wherein the vibration suppressor is elastic, and in mechanical communication with the electron emitter, wherein the vibration suppressor is configured to stabilize the emitter tip by absorbing vibrational energy of the emitter tip.

18. The method according to claim 16, wherein the vibration suppressor comprises a mass element and the coupling portion, the coupling portion is in mechanical communication with the electron emitter and the mass element, wherein the vibration suppressor is configured to stabilize the emitter tip by absorbing vibrational energy of the emitter tip.

19. A charged particle system, comprising:
an electron source that comprises an electron emitter that has an emitter tip, a support element that is connected to the emitter tip, and a vibration suppressor that (i) comprises an coupling portion, and (ii) is in mechanical communication with the electron emitter, wherein the vibration suppressor is configured to stabilize the emitter tip by absorbing vibrational energy of the emitter tip;
a sensing unit; and
optics configured to illuminate a sample with an electron beam that comprises electrons emitted from the electron tip, and (ii) direct to the sensing unit charged particles emitted from the sample due to the illumination of the sample with the electron beam.

20. The charged particle system according to claim 19, wherein the vibration suppressor is elastic, and in mechanical communication with the electron emitter, wherein the vibration suppressor is configured to stabilize the emitter tip by absorbing vibrational energy of the emitter tip.
